(19) United States
(12) Patent Application Publication
(10) Pub. No.: US 2025/0003695 A1
(43) Pub. Date: Jan. 2, 2025

(54) VARIABLE HEAT PIPE THICKNESS AND DIAMETER FOR DIRECT HEAT PIPE ATTACHMENT AND IMPROVED THERMAL MANAGEMENT

(71) Applicant: Intel Corporation, Santa Clara, CA (US)

(72) Inventors: Juha Paavola, Hillsboro, OR (US); Kari Mansukoski, Hillsboro, OR (US); Sami Heinisuo, Dallas, OR (US)

(21) Appl. No.: 18/345,597

(22) Filed: Jun. 30, 2023

(51) Int. Cl. F28D 15/04; F28D 15/02

(52) U.S. Cl. CPC F28D 15/046; F28D 15/0233; F28D 15/0275

(57) ABSTRACT

Techniques are disclosed for manufacturing a heat pipe that includes a variable wall thickness and/or a variable diameter. The heat pipe may be formed by subjecting a pipe to a thickness processing and an expansion processing. The heat pipe may include a first portion and a second portion. The first portion may have a first diameter and a first wall thickness. The second portion may have a second diameter larger than the first diameter, and a second wall thickness larger than the first wall thickness.

### TECHNICAL FIELD

The disclosure generally relates to heat pipes and method of manufacturing heat pipes, including a heat pipe with variable pipe thickness and diameter for improved thermal management.

### BACKGROUND

A heat pipe is a highly efficient heat transfer device used for the transportation of thermal energy from a heat source to a heat sink. It relies on the principles of phase change and capillary action to achieve rapid and efficient heat transfer. Heat pipes typically consist of a sealed, evacuated tube containing a working fluid, such as water, methanol. ammonia, or a refrigerant. The operation of a heat pipe is based on the heat transfer cycle involving evaporation, condensation, and phase change. When heat is applied to the evaporator section of the heat pipe, the working fluid absorbs this heat and undergoes a phase change from liquid to vapor. The resulting vapor flows toward the cooler end of the heat pipe, driven by the pressure gradient established within the system.

Conventional heat pipe installations include a cold plate to enhance the overall performance and effectiveness of the heat pipe system. A cold plate is typically a flat metal plate that is thermally connected to the heat sink or the component to be cooled. It acts as an interface between the heat pipe and the heat sink, facilitating efficient heat transfer. The use of cold plates requires an increased footprint, while adding additional thickness to the heat pipe system.

The primary purpose of a cold plate is to spread the heat transferred by the heat pipe over a larger surface area, thereby improving thermal dissipation. It helps in achieving uniform temperature distribution and reducing hotspots, especially when dealing with high heat loads or localized sources of heat. The cold plate typically has fins or other cooling structures to enhance convective heat transfer to the surrounding air.

### BRIEF DESCRIPTION OF THE DRAWINGS/FIGURES

The accompanying drawings, which are incorporated herein and form a part of the specification, illustrate the present disclosure and, together with the description, and further serve to explain the principles of the disclosure and to enable a person skilled in the pertinent art to make and use the techniques discussed herein.

FIG. 1 illustrates a heat pipe system including a heat pipe with a variable thickness and diameter according to the disclosure.

FIG. 2 illustrates a heat pipe system including a heat pipe with a variable thickness and diameter according to the disclosure.

FIGS. 3A-3C include cross-sectional views of a heat pipe thickness-processing mold taken along line 3D-3D as shown in FIG. 3D, where FIGS. 3A-3B show a process flow of the heat pipe thickness-processing operations, according to the disclosure.

FIG. 3D is a top view of a heat pipe thickness-processing mold according to the disclosure, including cross-sectional line 3D-3D.

FIGS. 4A-4C include cross-sectional views of a heat pipe expansion-processing mold taken along line 4D-4D as shown in FIG. 4D, where FIGS. 4A-4C show a process flow of the heat pipe diameter-processing operations, according to the disclosure.

FIG. 4D is a top view of a heat pipe diameter-processing mold according to the disclosure, including cross-sectional line 4D-4D.

FIG. 5 illustrates an operational flowchart of a method for forming a heat pipe with a variable thickness and diameter according to the disclosure.

The present disclosure will be described with reference to the accompanying drawings. The drawing in which an element first appears is typically indicated by the leftmost digit(s) in the corresponding reference number.

### DETAILED DESCRIPTION

The following detailed description refers to the accompanying drawings that show, by way of illustration, exemplary details in which the disclosure may be practiced. In the following description, numerous specific details are set forth in order to provide a thorough understanding of the present disclosure. However, it will be apparent to those skilled in the art that the various designs, including structures, systems, and methods, may be practiced without these specific details. The description and representation herein are the common means used by those experienced or skilled in the art to most effectively convey the substance of their work to others skilled in the art. In other instances, well-known methods, procedures, and components have not been described in detail to avoid unnecessarily obscuring the disclosure.

The present disclosure provides an advantageous solution to improve the transportation of thermal energy from a heat source to a heat sink and improving thermal dissipation without requiring a cold plate between the heat pipe and the heat source. The disclosure provides a heat pipe with a variable pipe thickness and/or diameter for improved thermal management while reducing the overall size of the heat pipe system by not requiring a cold plate.

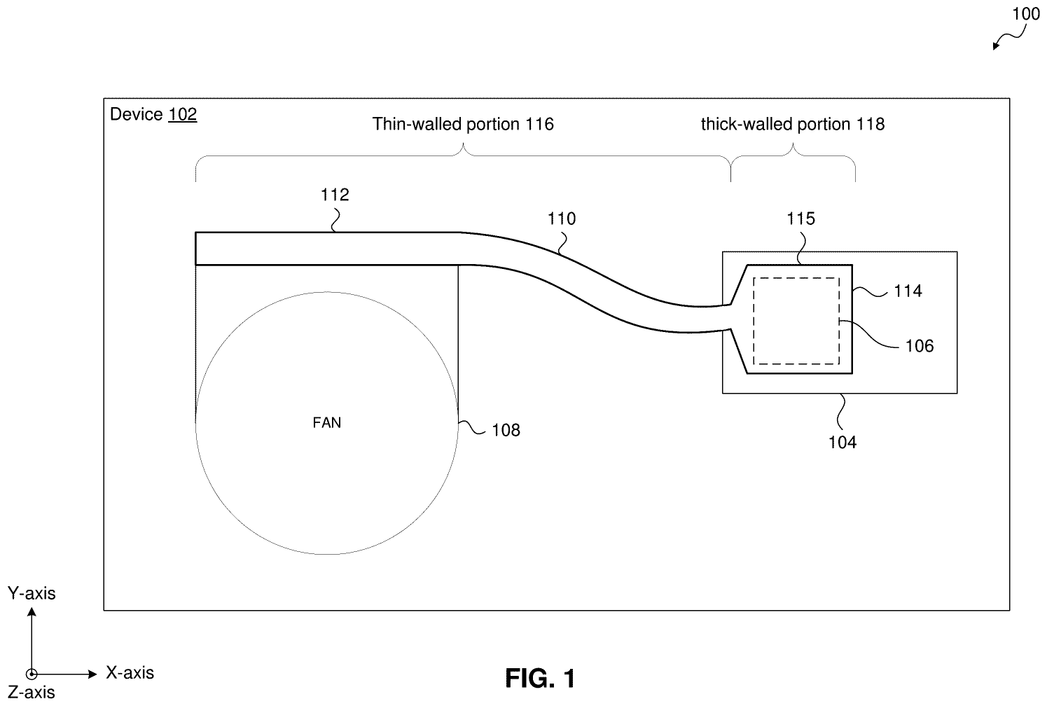

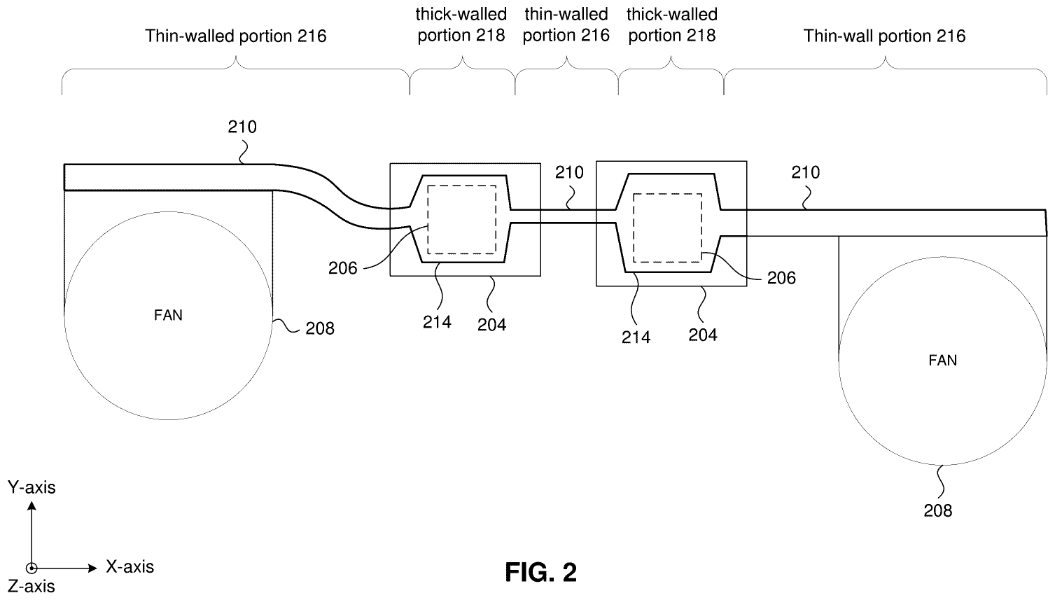

FIG. 1 illustrates a heat pipe system 100 according to the disclosure. The heat pipe system 100 may include a heat pipe 110 that includes a first portion 116 and a second portion 118. The first portion 116 and the second portion 118 may be located at opposite ends of the heat pipe 110, but other configurations are possible (e.g., see FIG. 2).

The heat pipe 110 may be a sealed, evacuated tube. Which may be made of one or more metals, metal alloys, superalloys, and/or other materials with high thermal conductivity. For example, the heat pipe 110 may be made of copper, aluminum, or other metal or metal alloy. The internal chamber formed within the heat pipe 110 may contain a working fluid, such as water, methanol. ammonia, and/or a refrigerant.

According to the disclosure, the first portion 116 may be a thin-walled portion 116 while the second portion 118 may be a thick-walled portion 118 having a greater wall thickness when compared to the wall thickness of the thin-walled portion 116. As illustrated in FIG. 1, the heat pipe system 100 may be installed within a device 102, such as an electronic device (e.g., computer, mobile phone, or other electronic device in which thermal management may be needed). The increased wall thickness in the thick-walled portion 118 provides a greater thermal mass, thereby providing increased heat absorption and/or dissipation as compared to the thin-walled portion 116 of the heat pipe 110.

In an example installation, the first end 112 may be thermally connected to a heat sink (or other heat/thermal dissipater) 108 (e.g., fan) and a second end 114 may be connected to a heat source 106, such as an integrated circuit (e.g. processor, etc.). For example, the heat source may be a die 106 of a system-on-chip (SOC) package 104. The heat pipe 110 may be configured to transfer heat from one portion of the heat pipe 110 to another. For example, the heat pipe 110 may transfer heat from the second end 114 (e.g., heat generated by the heat source 106 and transferred to the second end 114) to the first end 112. The heat transferred to the first end 112 may then be transferred to, and/or dissipated by, the heat sink 108. For example, a fan 108 may generate an airflow to cool the first end 112 of the heat pipe 110 and/or cool a heat sink (e.g. a radiator) thermally connected to the first end 112.

As illustrated in FIG. 1, the first end 112 may be in the thin-walled portion 116 of the heat pipe 110 and the second end 114 may be in the thick-walled portion 118. For example, the thin-walled portion 116 may have a first wall thickness and the thick-walled portion 118 may have a second wall thickness that is greater than the first wall thickness. According to the disclosure, the thin-walled portion 116 of the heat pipe 110 may have a wall thickness that is the same or similar to the original wall thickness of the pipe material used to fabricated the heat pipe 110, while the thick-walled portion 118 of the heat pipe 110 may have a greater wall thickness in which the original wall thickness of the pipe material has been increased during fabrication of the heat pipe 110. According to the disclosure, the heat pipe 110 having the thin-walled portion 116 and the thick-walled portion 118 may be formed from a single pipe structure. Alternatively, the thin-walled portion 116 may be a first pipe structure and the thick-walled portion 118 may be a second pipe structure having an increased wall thickness as compared to the first pipe structure, where the first and second pipe structures are joined together to form heat pipe 110.

According to the disclosure, the second end 114 of the heat pipe 110 may have a larger diameter than the diameter of the first end 112. For example, the thin-walled portion 116 may have a first diameter and the thick-walled portion 118 may have a second diameter that is greater than the first diameter. That is, the heat pipe 110 may have a variable diameter along its length and/or a variable wall thickness along its length. According to the disclosure, the wall thickness may from the thin-walled portion 116 to the thick-walled portion 118 and/or the diameter of the heat pipe 110 may vary from the first end 112 to the second end 115. Although the heat pipe 110 as described in FIG. 1 has two different wall thicknesses and/or two different diameters, the heat pipe 110 may include one or more additional portions with one or more other diameter and/or wall thickness dimensions. The increased diameter provides a larger surface area (e.g., larger contact area) at the second end 114 to improve heat transfer from the heat source into the second end 114 of the heat pipe 110. Further, the increased thickness of the second end 114 provides an increased thermal mass in the thick-walled portion 118 to increase heat dissipation and/or absorption by the second end 114 of the heat pipe 110.

The second end 114 with the increased diameter may be configured as an enlarged pad 115, such as when the heat pipe is flattened during the manufacturing process. The enlarged diameter pipe may be flattened to form the pad 115. The heat pipe 110 will have an increased width (e.g., when flattened) at the second end 114 due to the heat pipe 110 having a larger diameter in this portion of the heat pipe 110. That is, the heat pipe 110 (e.g., when flattened) may have a first width in the thin-walled portion 116 and a second width in the thick-walled portion 118, where the second width is greater than the first width.

According to the disclosure, when flattened, the first portion (e.g., thin-walled portion 116) may have a first height smaller than the first width, and the second portion (thick-walled portion 118) may have a second height smaller than the second width. The second height may be larger than the first height due to the heat pipe 110 having an increased wall thickness in the thick-walled portion 118. In this configuration, the widths (e.g., y-direction) are perpendicular to the heights (e.g. z-direction), which are both perpendicular to the length (e.g. x-direction) of the heat pipe 110.

Due to the increased diameter/width of the heat pipe 110 at the second end 114, the pad 115 formed at the second end 114 will have an increased surface area (e.g., lateral area defined by the x-y directions) as compared to other portion(s) of the heat pipe 110, which will increase the surface area of the heat pipe 110 in contact (e.g., thermal contact) with the heat source 106. That is, the first end 112 (e.g., contacting the heat sink 108) may have a first lateral area (e.g., as defined in the x-y directions-length and width of the heat pipe 110) and the second end 114 forming the pad 115 may have a second lateral area (e.g., as defined in the x-y directions—length and width of the heat pipe 110), where the second lateral area is larger than the first lateral area.

According to the disclosure, the enlarged pad 115 of the heat pipe 110 may be directly connected to the heat source 106. In this example, the direct connection is established by omitting a cold plate or other heat dissipator between the pad 115 and the heat source 106. According to the disclosure, the direct connection may include a configuration in which a thermal or heat paste, thermal compound, thermal grease, or thermal interface material or gel, etc. is disposed between the heat pipe 110 and the heat source 106 and/or heat sink 108. That is, the direct connection may refer to configurations in which a cold plate is omitted. In other configurations, a direction connection may refer to a configuration in which the thermal or heat paste, etc. is also omitted.

The heat pipe 110 advantageously reduces the overall size, thickness, and/or footprint of the heat pipe system 100, while increases the thermal conductivity and thermal dissipation by including the enlarged pad 115 with an increased wall thickness as compared to one or more other portions of the heat pipe 110. Although the heat pipe system 100 may be configured without a cold plate as described above, the heat pipe system 100 is not limited thereto, and the heat pipe 110 may be used with a cold plate. Alternatively, if a cold plate is used, the heat pipe system 100 may advantageously use a cold plate of reduced thickness and/or size as a result of the heat pipe's increased wall thickness and diameter (e.g., lateral area) at the second end portion 114. In this example, the heat pipe 110 may provide an improved transportation of thermal energy and improved thermal dissipation even in configurations in which a cold plate is omitted or a cold plate of reduced dimensions is used.

FIG. 2 illustrates a heat pipe system 200 according to the disclosure. The heat pipe system 200 may include a heat pipe 210 that is similar to the heat pipe 110, but includes multiple thin-walled portions 216 and multiple thick-walled portions 218. According to the disclosure, the heat pipe system 200 is a double-ended system that includes two heat sources 206 and two heat sinks 208, which are similar to the heat source 106 and heat sink 108 of FIG. 1. In the system 200, the thick-walled portions 218 have an increased diameter as compared to the thin-walled portions 216 of the heat pipe 210, similar to the heat pipe system 100.

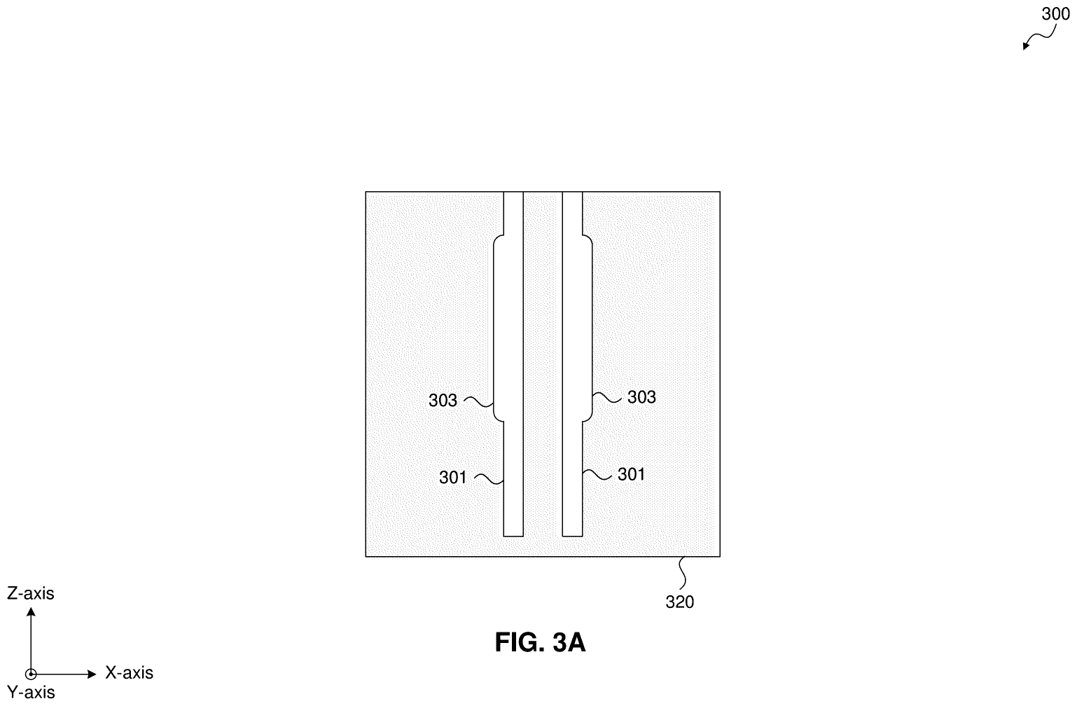

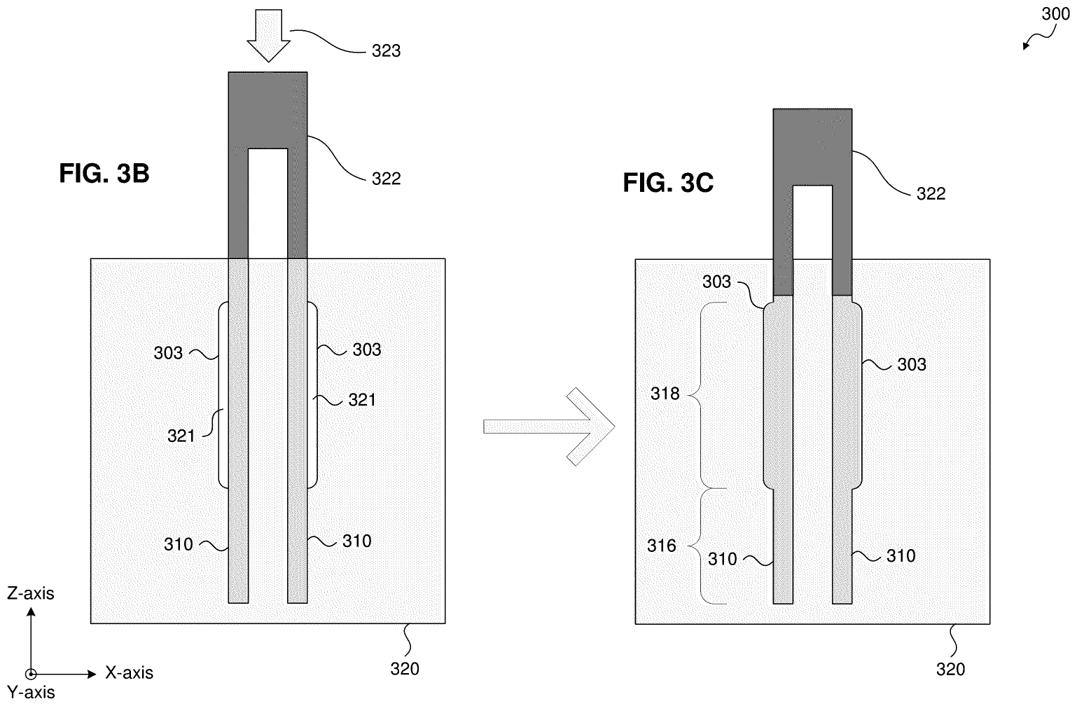

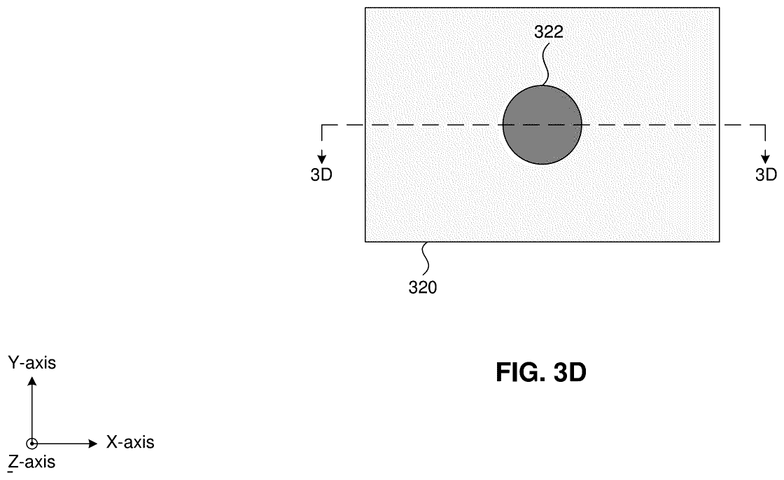

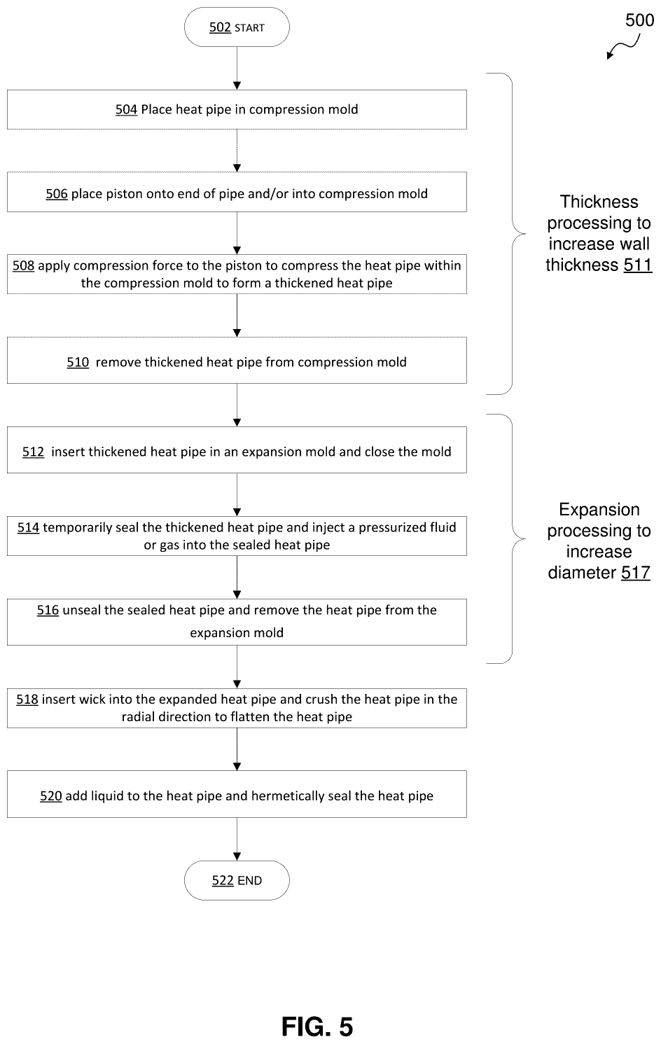

FIGS. 3A-3C each show a cross-sectional view of a heat pipe thickness-processing mold taken along line 3D-3D as shown in FIG. 3D, where FIGS. 3A-3C collectively show a process flow 300 of the heat pipe thickness-processing operations according to the disclosure. Discussion of the process flow 300 as shown in FIGS. 3A-3C may reference the flowchart of the method 500 shown in FIG. 5, including one or more operations of the thickness processing 511.

The method 300 includes the compression of the pipe 310 using mold 320 and piston 322. As shown in FIG. 3A, the mold 320 includes a chamber 301 configured to accept a pipe 310 inserted therein (as shown in FIGS. 3B-3C). The chamber, when viewed from above forms a donut shape. That is, the chamber 301 is cylindrically shaped, where the cylinder-shaped chamber includes a concentric cylindrical core.

The chamber 301 includes an expansion chamber 303 that has an increased width (e.g., in the radial direction). For example, the donut shaped chamber 301 has an increased diameter in the section of the expansion chamber 303. As shown in FIG. 3B, when a pipe 310 is inserted in the chamber 301, an expansion void 321, which is adjacent to an outer surface of the pipe 310, is formed in the expansion chamber 303.

FIG. 3B shows a pipe 310 inserted (e.g., in the −Z direction) in the chamber 301 (see operation 504 of FIG. 5), which forms the expansion void 321 around a portion of the pipe 310. Following insertion of the pipe 310, a piston 322 is disposed on the top of the inserted pipe 310 (see operation 506 of FIG. 5). The piston 322 may be partially inserted in the chamber 301 if the pipe 310 does not extend to the top of the mold 320. A compression force 323 may then be applied to the piston 322 in an axial direction of the pipe 310 (see operation 508 of FIG. 5), which coincides with an axial direction of the chamber 301 (e.g., in the −Z direction).

FIG. 3C shows the pipe 310 having been compressed by the compression force 322 applied to the piston 322. The compression of the pipe 310 causes the pipe 310 to expand into and at least partially fill the expansion void 321, thereby increasing the wall thickness along the pipe 310 in the section of the mold including the expansion chamber 303. The resulting compressed pipe 310 will have a thick-walled portion 318 and a thin-walled portion 310. In this example, the thin-walled portion 310 has the same or similar wall thickness as the pre-compressed pipe, while the think-walled portion 318 has an increased wall thickness.

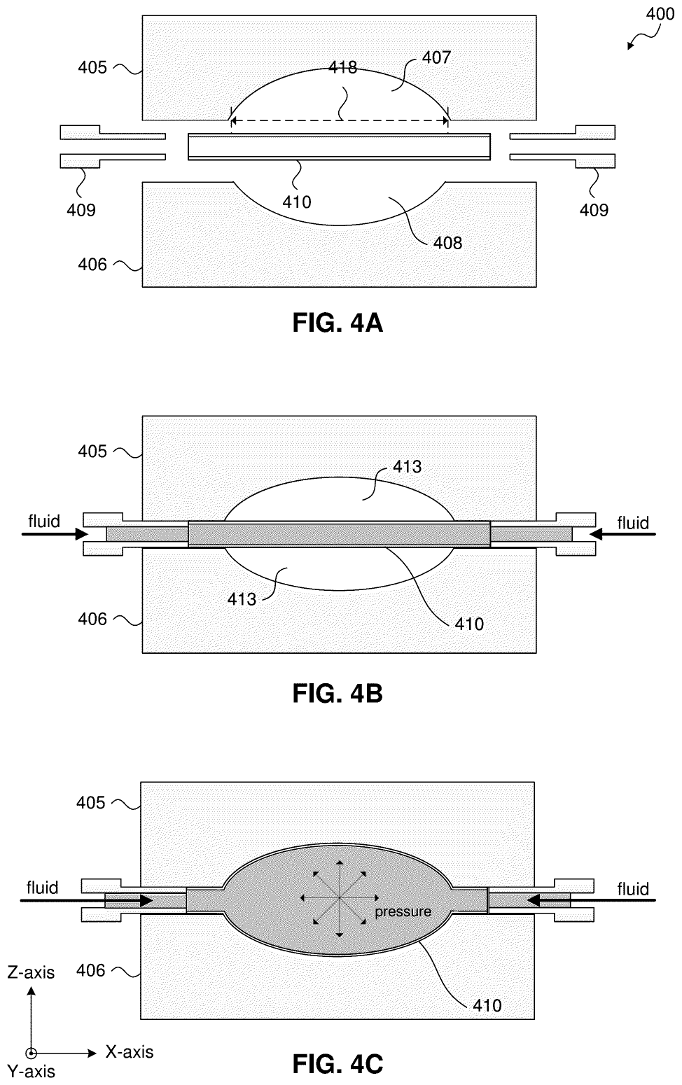

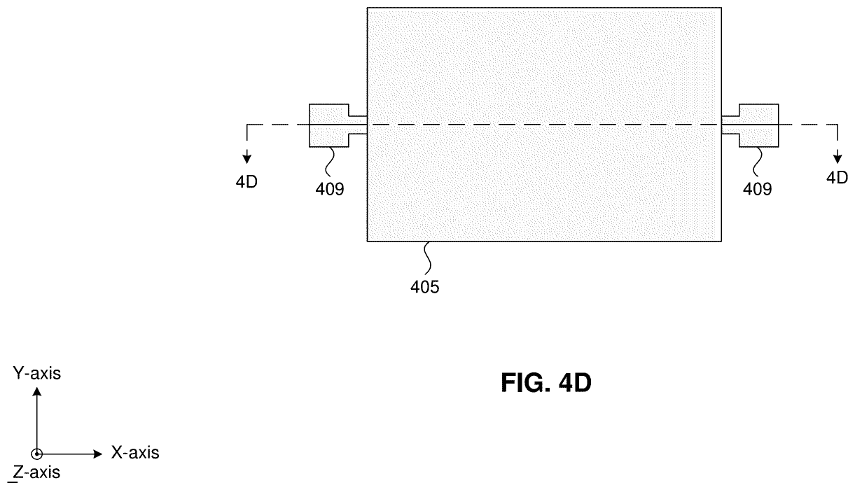

FIGS. 4A-4C each show a cross-sectional view of a heat pipe expansion-processing mold taken along line 4D-4D as shown in FIG. 4D, where FIGS. 4A-4C collectively show a process flow 400 of the heat pipe expansion-processing operations according to the disclosure. The expansion processing may be used to increase the diameter of the pipe 410 in at least a portion (e.g. portion 418) of the pipe 410. Discussion of the process flow 400 as shown in FIGS. 4A-4C may reference the flowchart of the method 500 shown in FIG. 5, including one or more operations of the expansion processing 517.

The method 400 includes the expansion of the pipe 410 using a mold 405, 406. The mold may include a first portion 405 (e.g., top portion) and a second portion 405 (e.g., bottom portion). The first portion 405 may include a first void 407 and the second portion 406 may include a second void 408. When the first and second portions 405, 406 of the mold are closed together, the first and second void 407, 408 form an internal chamber 413. When the closed mold has the pipe 410 inserted therein, the internal chamber 413 surrounds at least a portion of the pipe 410 as shown in FIG. 4B. The portion 418 of the pipe 418 is within the voids 407, 408 (internal chamber 413, and will be subject to expansion processing as shown in FIGS. 4B-4C. The portion 418 may correspond to the thick-walled portion 318 so that the expanded portion 418 of the pipe 410 is a portion that has been subject to thickness processing to increase the wall thickness of the pipe.

As shown in FIG. 4A, the pipe 410 may be placed or inserted in the mold (see operation 512 of FIG. 5). Sealing members 409 may then be placed in the adjacent to the pipe 410. The sealing member 409 are configured to contact the ends of the pipe in a sealing manner and couple to a fluid source. The sealing members 409 may be referred to as couplings.

When the first portion 405 and the second portion 406 are brought together to close the mold, the first portion 405 and the second portion 406 may sandwich the sealing members 409 and the pipe 410 between the first portion 405 and the second portion 406 as shown in FIG. 4B. After the mold is closed, a fluid from a fluid source is introduced into the hollow center of the pipe 410 via the sealing members 409 (see operation 514 of FIG. 5). The fluid may be water or other fluid.

As shown in FIG. 4C, the fluid is pressurized, which places the pipe 410 under pressure and the internal forces cause the pipe 410 to expand outward and at least partially fill the chamber 413. Additionally, or alternatively, a gas (e.g., air) may be used and introduced into the pipe 410 to cause the expansion. According to the disclosure, the expansion processing may be tube hydroforming, pneumatic forming, or other mechanical expansion processing. After the pipe 410 is expanded, the fluid may be removed, and the expanded pipe 410 may be removed from the mold (see operation 516 of FIG. 5).

FIG. 5 illustrates a flowchart of a method 500 for forming a heat pipe with a variable thickness and diameter according to the disclosure. Two or more of the various operations illustrated in FIG. 5 may be performed simultaneously in some configurations. Further, the order of the various operations is not limiting and the operations may be performed in a different order in some configurations.

The flowchart 500 begins at operation 502 and transitions to operation 504, where the pipe is placed in the compression mold (e.g., see FIG. 3B).

After operation 504, the flowchart 500 transitions to operation 506, where the piston is placed on the top of the inserted pipe. For example, as shown in FIG. 3B, the piston 322 may be disposed on the top of the inserted pipe 310. The piston 322 may be partially inserted in the chamber 301 if the pipe 310 does not extend to the top of the mold 320.

After operation 506, the flowchart 500 transitions to operation 508, where a compression force is applied to the piston to compress the heat pipe within the compression mold to form a thickened heat pipe. For example, as shown in FIG. 3B, a compression force 323 may be applied to the piston 322 in an axial direction of the pipe 310 to increase a wall thickness of at least a portion of the heat pipe. The compression of the pipe 310 causes the pipe 310 to expand into and at least partially fill the expansion void 321, thereby increasing the wall thickness along the pipe 310 in the section of the mold including the expansion chamber 303. The resulting compressed pipe 310 will have a thick-walled portion 318 and a thin-walled portion 310.

After operation 508, the flowchart 500 transitions to operation 510, where the thickened heat pipe may be removed from the compression mold. Operations 504 to 510 may collectively be referred to as thickness processing 511.

At operation 512, a thickened heat pipe may be inserted in an expansion mold. The mold may then be closed around the pipe. For example, as shown in FIG. 4A, the mold may include a first portion 405 (e.g., top portion) and a second portion 405 (e.g., bottom portion). The first portion 405 may include a first void 407 and the second portion 406 may include a second void 408. When the first and second portions 405, 406 of the mold are closed together, the first and second void 407, 408 form an internal chamber 413. The portion 418 of the pipe 418 is within the voids 407, 408 (internal chamber 413, and will be subject to expansion processing as shown in FIGS. 4B-4C. The portion 418 may correspond to the thick-walled portion 318 so that the expanded portion 418 of the pipe 410 is a portion that has been subject to thickness processing to increase the wall thickness of the pipe. When the first portion 405 and the second portion 406 are brought together to close the mold, the first portion 405 and the second portion 406 may sandwich the sealing members 409 and the pipe 410 between the first portion 405 and the second portion 406 as shown in FIG. 4B.

After operation 512, the flowchart 500 transitions to operation 514, where inserted pipe and the mold are sealed, and a pressurized fluid and/or gas is applied to the mold and introduced into the hollow portion of the pipe enclosed in the mold As shown in FIG. 4C, the fluid is pressurized, which places the pipe 410 under pressure and the internal forces cause the pipe 410 to expand outward and at least partially fill the chamber 413. Additionally, or alternatively, a gas (e.g., air) may be used and introduced into the pipe 410 to cause the expansion. According to the disclosure, the expansion processing may be tube hydroforming, pneumatic forming, or other mechanical expansion processing.

After operation 514, the flowchart 500 transitions to operation 516, where the pipe and mold may be unsealed, the fluid and/or gas may be removed from the pipe, and the pipe may be removed from the mold. For example, after the pipe 410 is expanded, the fluid may be removed, and the expanded pipe 410 may be removed from the mold. Operations 512 to 516 may collectively be referred to as expansion processing 517.

After operation 516, the flowchart 500 transitions to operation 518, where a wick may be inserted into the thickened and expanded pipe. The pipe may then be flattened/crushed in the radial direction.

After operation 518, the flowchart 500 transitions to operation 520, where a working fluid may be added to the pipe and the pipe may be hermetically sealed to form the heat pipe with a variable thickness and diameter according to the disclosure.

After operation 520, the flowchart 500 transitions to operation 522, where the method ends.

### Examples

The following examples pertain to various techniques of the present disclosure.

An example (e.g., example 1) relates to a heat pipe, comprising: a first portion including: a first diameter and a first wall thickness; a second portion including: a second diameter larger than the first diameter, and a second wall thickness larger than the first wall thickness.

Another example (e.g., example 2) relates to a previously-described example (e.g., example 1), wherein the second portion has a greater thermal mass than the first portion.

Another example (e.g., example 3) relates to a previously-described example (e.g., one or more of examples 1-2), wherein the second portion is configured to be disposed on a heat source without a cold plate.

Another example (e.g., example 4) relates to a previously-described example (e.g., example 3), wherein the heat source is an integrated circuit.

Another example (e.g., example 5) relates to a previously-described example (e.g., one or more of examples 1-4), wherein the second portion is configured to form a flattened pad having a larger lateral area than the first portion in response to the heat pipe being flattened.

Another example (e.g., example 6) relates to a previously-described example (e.g., one or more of examples 1-5), wherein the heat pipe is formed of copper or a copper alloy.

An example (e.g., example 7) relates to a heat pipe, comprising: a first portion extending a first length and having a first wall thickness and a first width; and a second portion extending a second length and having a second wall thickness larger than the first wall thickness and a second width larger than the first width.

Another example (e.g., example 8) relates to a previously-described example (e.g., example 7), wherein the first portion is a first flattened portion having a first height smaller than the first width, and the second portion is a second flattened portion having a second height smaller than the second width.

Another example (e.g., example 9) relates to a previously-described example (e.g., example 8), wherein the first width is perpendicular to the first height and the second width is perpendicular to the second height.

Another example (e.g., example 10) relates to a previously-described example (e.g., one or more of examples 8-9), wherein the first length is perpendicular to the first width and the first height, and the second length is perpendicular to the second width and the second height.

Another example (e.g., example 11) relates to a previously-described example (e.g., one or more of examples 7-10), wherein the first width is perpendicular to the first length and the second length width is perpendicular to the second width.

Another example (e.g., example 12) relates to a previously-described example (e.g., one or more of examples 7-11), wherein the second portion has a greater thermal mass than the first portion.

Another example (e.g., example 13) relates to a previously-described example (e.g., one or more of examples 7-12), wherein the second portion is configured to be disposed on a heat source without a cold plate.

Another example (e.g., example 14) relates to a previously-described example (e.g., one or more of examples 7-13), wherein the first portion has a first lateral area defined by the first length and the first width, and the second portion has a second lateral area defined by the second length and the second width, the second lateral area being larger than the first lateral area.

An example (e.g., example 15) relates to a method for forming a heat pipe having a first portion and second portion, comprising: performing a thickness processing on the heat pipe to increase a wall thickness of the first portion of the heat pipe to form a thickened heat pipe including the first and second portions, the first portion having a first wall thickness that is larger than a second wall thickness of the second portion; and performing an expansion processing on the thickened heat pipe to increase a diameter of the first portion of the thickened heat pipe to form an expanded heat pipe including the first and second portions, the first portion having a first diameter that is larger than a second diameter of the second portion.

Another example (e.g., example 16) relates to a previously-described example (e.g., example 15), further comprising: inserting a wick into the expanded heat pipe in an axial direction of the expanded heat pipe; and crushing the heat pipe in a radial direction perpendicular to the axial direction to form a flattened heat pipe.

Another example (e.g., example 17) relates to a previously-described example (e.g., one or more of examples 15-16), further comprising: adding a working fluid into an interior cavity of the flattened heat pipe; and hermetically sealing the flattened heat pipe having the working fluid therein.

Another example (e.g., example 18) relates to a previously-described example (e.g., one or more of examples 15-17), wherein performing the thickness processing on the heat pipe comprises compressing the heat pipe in an axial direction to increase the wall thickness of the first portion of the heat pipe.

Another example (e.g., example 19) relates to a previously-described example (e.g., one or more of examples 15-18), wherein performing the thickness processing on the heat pipe further comprises: prior to compressing the heat pipe in the axial direction, placing the heat pipe in a mold having a first section and a second section, the first section having a void adjacent to an outer surface of the heat pipe and extending in a radial direction away from the heat pipe, and the second section of the mold contacts the outer surface of the heat pipe, wherein the void extends in the axial direction a distance corresponding to an axial distance of the first portion of the heat pipe, the compressing of the heat pipe causing the wall thickness of the first portion of the heat pipe to increase and at least partially fill the void.

Another example (e.g., example 20) relates to a previously-described example (e.g., one or more of examples 15-19), wherein performing the expansion processing on the thickened heat pipe comprises temporarily sealing the heat pipe and injecting a pressurized fluid or gas into the temporarily sealed heat pipe to cause the diameter of the first portion of the thickened heat pipe to increase to form the expanded heat pipe.

An example (e.g., example 21) relates to a system comprising: a heat pipe including:
a first portion including: a first diameter and a first wall thickness; a second portion including: a second diameter larger than the first diameter, and a second wall thickness larger than the first wall thickness, wherein the second portion of the heat pipe is configured to thermally connect to a heat source; and a fan configured to generate an airflow to cool the first portion of the heat pipe, wherein the heat pipe is configured to transfer heat generated by the heat source from the second portion to the first portion.

An example (e.g., example 22) relates to a system comprising: a heat pipe including: a first portion including: a first diameter and a first wall thickness; a second portion including: a second diameter larger than the first diameter, and a second wall thickness larger than the first wall thickness, wherein the second portion of the heat pipe is configured to thermally connect to a heat source; and a thermal dissipater configured to dissipate heat from the first portion of the heat pipe, wherein the heat pipe is configured to transfer heat generated by the heat source from the second portion to the first portion.

Another example (e.g., example 23) relates to a previously-described example (e.g., example 22), wherein the thermal dissipater comprises a heat sink.

Another example (e.g., example 24) relates to a previously-described example (e.g., one or more of examples 22-23), wherein the thermal dissipater comprises a fan.

An example (e.g., example 25) relates to a system comprising: thermal transfer means including: a first portion including: a first diameter and a first wall thickness; a second portion including: a second diameter larger than the first diameter, and a second wall thickness larger than the first wall thickness, wherein the second portion of the thermal transfer means is configured to thermally connect to a heat source; and thermal dissipation means for generating an airflow to cool the first portion of the thermal transfer means, wherein the thermal transfer means is configured to transfer heat generated by the heat source from the second portion to the first portion.

An example (e.g., example 26) relates to a system comprising: thermal transfer means including: a first portion including: a first diameter and a first wall thickness; a second portion including: a second diameter larger than the first diameter, and a second wall thickness larger than the first wall thickness, wherein the second portion of the thermal transfer means is configured to thermally connect to a heat source; and thermal dissipation means for dissipating heat from the first portion of the thermal transfer means, wherein the thermal transfer means is configured to transfer heat generated by the heat source from the second portion to the first portion.

Another example (e.g., example 27) relates to a previously-described example (e.g., one or more of examples 25-26), wherein the thermal transfer means has an axial length extending in an axial direction, the first portion forming a first axial section of the thermal transfer means extending in the axial direction and the second portion forming a second axial section of the thermal transfer means extending in the axial direction.

Another example (e.g., example 28) relates to a previously-described example (e.g., one or more of examples 25-27), wherein the thermal transfer means is a heat pipe.

Another example (e.g., example 29) relates to a previously-described example (e.g., one or more of examples 25-28), wherein the thermal dissipation means comprises a fan.

Another example (e.g., example 30) relates to a previously-described example (e.g., one or more of examples 25-29), wherein the thermal dissipation means comprises a heat sink.

Another example (e.g., example 31) relates to a previously-described example (e.g., one or more of examples 21-30), wherein the second portion is configured to be disposed on the heat source without a cold plate.

Another example (e.g., example 32) relates to a previously-described example (e.g., one or more of examples 21-31), wherein the second portion has a greater thermal mass than the first portion.

Another example (e.g., example 33) relates to a previously-described example (e.g., one or more of examples 21-32), wherein the heat source is an integrated circuit.

Another example (e.g., example 34) relates to a previously-described example (e.g., one or more of examples 21-33), wherein the second portion is configured to form a flattened pad having a larger lateral area than the first portion.

Another example (e.g., example 35) relates to a heat pipe formed by the method of one or more of examples 15-20.

Another example (e.g., example 36) relates to a thermal transfer means formed by the method of one or more of examples 15-20.

Another example (e.g., example 37) relates to a heat pipe as shown and described.

Another example (e.g., example 38) relates to a thermal transfer means as shown and described.

Another example (e.g., example 39) relates to an apparatus as shown and described.

Another example (e.g., example 40) relates a method as shown and described.

### CONCLUSION

The aforementioned description will so fully reveal the general nature of the implementation of the disclosure that others can, by applying knowledge within the skill of the art, readily modify and/or adapt for various applications such specific implementations without undue experimentation and without departing from the general concept of the present disclosure. Therefore, such adaptations and modifications are intended to be within the meaning and range of equivalents of the disclosed implementations, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

Each implementation described may include a particular feature, structure, or characteristic, but every implementation may not necessarily include the particular feature, structure, or characteristic. Moreover, such phrases are not necessarily referring to the same implementation. Further, when a particular feature, structure, or characteristic is described in connection with an implementation, it is submitted that it is within the knowledge of one skilled in the art to affect such feature, structure, or characteristic in connection with other implementations whether or not explicitly described.

The exemplary implementations described herein are provided for illustrative purposes, and are not limiting. Other implementations are possible, and modifications may be made to the exemplary implementations. Therefore, the specification is not meant to limit the disclosure. Rather, the scope of the disclosure is defined only in accordance with the following claims and their equivalents.

Throughout the drawings, it should be noted that like reference numbers are used to depict the same or similar elements, features, and structures, unless otherwise noted.

The terms “at least one” and “one or more” may be understood to include a numerical quantity greater than or equal to one (e.g., one, two, three, four, [ . . . ], etc.). The term “a plurality” may be understood to include a numerical quantity greater than or equal to two (e.g., two, three, four, five, [ . . . ], etc.).

The words “plural” and “multiple” in the description and in the claims expressly refer to a quantity greater than one. Accordingly, any phrases explicitly invoking the aforementioned words (e.g., “plural [elements]”, “multiple [elements]”) referring to a quantity of elements expressly refers to more than one of the said elements. The terms “group (of)”, “set (of)”, “collection (of)”, “series (of)”, “sequence (of)”, “grouping (of)”, etc., and the like in the description and in the claims, if any, refer to a quantity equal to or greater than one, i.e., one or more. The terms “proper subset”, “reduced subset”, and “lesser subset” refer to a subset of a set that is not equal to the set, illustratively, referring to a subset of a set that contains less elements than the set.

The phrase “at least one of” with regard to a group of elements may be used herein to mean at least one element from the group consisting of the elements. The phrase “at least one of” with regard to a group of elements may be used herein to mean a selection of: one of the listed elements, a plurality of one of the listed elements, a plurality of individual listed elements, or a plurality of a multiple of individual listed elements.

1. A heat pipe, comprising:
a first portion including: a first diameter and a first wall thickness;
a second portion including: a second diameter larger than the first diameter, and a second wall thickness larger than the first wall thickness.

2. The heat pipe of claim 1, wherein the second portion has a greater thermal mass than the first portion.

3. The heat pipe of claim 1, wherein the second portion is configured to be disposed on a heat source without a cold plate.

4. The heat pipe of claim 3, wherein the heat source is an integrated circuit.

5. The heat pipe of claim 1, wherein the second portion is configured to form a flattened pad having a larger lateral area than the first portion in response to the heat pipe being flattened.

6. The heat pipe of claim 1, wherein the heat pipe is formed of copper or a copper alloy.

7. A heat pipe, comprising:
a first portion extending a first length and having a first wall thickness and a first width; and
a second portion extending a second length and having a second wall thickness larger than the first wall thickness and a second width larger than the first width.

8. The heat pipe of claim 7, wherein the first portion is a first flattened portion having a first height smaller than the first width, and the second portion is a second flattened portion having a second height smaller than the second width.

9. The heat pipe of claim 8, wherein the first width is perpendicular to the first height and the second width is perpendicular to the second height.

10. The heat pipe of claim 9, wherein the first length is perpendicular to the first width and the first height, and the second length is perpendicular to the second width and the second height.

11. The heat pipe of claim 7, wherein the first width is perpendicular to the first length and the second length width is perpendicular to the second width.

12. The heat pipe of claim 7, wherein the second portion has a greater thermal mass than the first portion.

13. The heat pipe of claim 7, wherein the second portion is configured to be disposed on a heat source without a cold plate.

14. The heat pipe of claim 7, wherein the first portion has a first lateral area defined by the first length and the first width, and the second portion has a second lateral area defined by the second length and the second width, the second lateral area being larger than the first lateral area.

15. A method for forming a heat pipe having a first portion and second portion, comprising:
performing a thickness processing on the heat pipe to increase a wall thickness of the first portion of the heat pipe to form a thickened heat pipe including the first and second portions, the first portion having a first wall thickness that is larger than a second wall thickness of the second portion; and
performing an expansion processing on the thickened heat pipe to increase a diameter of the first portion of the thickened heat pipe to form an expanded heat pipe including the first and second portions, the first portion having a first diameter that is larger than a second diameter of the second portion.

16. The method of claim 15, further comprising:
inserting a wick into the expanded heat pipe in an axial direction of the expanded heat pipe; and
crushing the heat pipe in a radial direction perpendicular to the axial direction to form a flattened heat pipe.

17. The method of claim 16, further comprising: adding a working fluid into an interior cavity of the flattened heat pipe; and hermetically sealing the flattened heat pipe having the working fluid therein.

18. The method of claim 15, wherein performing the thickness processing on the heat pipe comprises compressing the heat pipe in an axial direction to increase the wall thickness of the first portion of the heat pipe.

19. The method of claim 15, wherein performing the thickness processing on the heat pipe further comprises:
prior to compressing the heat pipe in the axial direction, placing the heat pipe in a mold having a first section and a second section, the first section having a void adjacent to an outer surface of the heat pipe and extending in a radial direction away from the heat pipe, and the second section of the mold contacts the outer surface of the heat pipe,
wherein the void extends in the axial direction a distance corresponding to an axial distance of the first portion of the heat pipe, the compressing of the heat pipe causing the wall thickness of the first portion of the heat pipe to increase and at least partially fill the void.

20. The method of claim 15, wherein performing the expansion processing on the thickened heat pipe comprises temporarily sealing the heat pipe and injecting a pressurized fluid or gas into the temporarily sealed heat pipe to cause the diameter of the first portion of the thickened heat pipe to increase to form the expanded heat pipe.

21. A system comprising:
a heat pipe including:
a first portion including: a first diameter and a first wall thickness;
a second portion including: a second diameter larger than the first diameter, and a second wall thickness larger than the first wall thickness, wherein the second portion of the heat pipe is configured to thermally connect to a heat source; and
a fan configured to generate an airflow to cool the first portion of the heat pipe, wherein the heat pipe is configured to transfer heat generated by the heat source from the second portion to the first portion.
